(19) United States
(12) Patent Application Publication
(10) Pub. No.: US 2026/0239840 A1
(43) Pub. Date: Aug. 13, 2026

(54) DISPLAY PANEL AND ELECTRONIC DEVICE INCLUDING THE SAME

(71) Applicant: Samsung Display Co., Ltd., Yongin-si (KR)

(72) Inventor: Daehyuk IM, Yongin-si (KR)

(73) Assignee: Samsung Display Co., Ltd., Yongin-si (KR)

(21) Appl. No.: 19/447,952

(22) Filed: Jan. 13, 2026

(30) Foreign Application Priority Data
Feb. 7, 2025 (KR) 10-2025-0016111

(51) Int. Cl. H10K 59/131; H10K 102/00

(52) U.S. Cl. CPC H10K 59/131; H10K 2102/351

(57) ABSTRACT

Disclosed are electronic devices which include a display panel including a display area and a non-display area adjacent to the display area and an electronic component in the non-display area and electrically connected to the display panel. The display panel includes a pixel, a signal line electrically connected to the pixel, and a signal pad electrically connected with the signal line. The signal pad includes a first conductive pattern electrically connected to an end portion of the signal line, an insulating pattern on the first conductive pattern, and a second conductive pattern contacting the first conductive pattern and including a first metal line portion contacting an outer surface of the insulating pattern and a second metal line portion extending from the first metal line portion and protruding from the insulating pattern. The electronic component includes a bump defining a hole contacting the second metal line portion.

### CROSS-REFERENCE TO RELATED APPLICATIONS

This application claims priority under 35 U.S.C. § 119 to Korean Patent Application No. 10-2025-0016111 filed on Feb. 7, 2025, in the Korean Intellectual Property Office, the disclosures of which are incorporated by reference herein in their entireties.

### BACKGROUND

Embodiments of the present disclosure described herein relate to display panels and electronic devices including the same, and more particularly, relate to pad areas of a display panel and an electronic device.

Various electronic devices used in multimedia devices, such as a television, a mobile phone, a tablet computer, a car navigation device, a game machine, and the like, are being developed. Electronic devices may include a keyboard or a mouse as an input device and be equipped with input sensors, such as, for example, a touch panel, as an input device.

Electronic devices may include a display area activated in response to an electrical signal. Through the display area, the electronic device may sense an input applied from the outside and may display various images to provide information to a user.

Electronic devices may include a display panel and a circuit board. The display panel may be connected to the main board through the circuit board, and a driver chip may be mounted on the display panel. The driver chip or a film on which the driver chip is mounted may be bonded with the display panel through an anisotropic conductive film (ACF). However, high-temperature and high-pressure conditions may be required in the bonding process.

### SUMMARY

Embodiments of the present disclosure provide display panels with improved bonding reliability and electronic devices including the same.

According to some example embodiments, an electronic device includes a display panel including a display area and a non-display area adjacent to the display area and an electronic component in the non-display area and electrically connected to the display panel. The display panel includes a pixel, a signal line electrically connected to the pixel, and a signal pad electrically connected with the signal line. The signal pad includes a first conductive pattern electrically connected to an end portion of the signal line, an insulating pattern on the first conductive pattern, and a second conductive pattern configured to contact the first conductive pattern and includes a first metal line portion configured to contact an outer surface of the insulating pattern and a second metal line portion configured to extend from the first metal line portion and protrudes from the insulating pattern. The electronic component includes a bump defining a hole configured to contact the second metal line portion.

The first metal line portion may have a spiral shape.

The second metal line portion may include a first portion having a same thickness as the first metal line portion and a second portion that has a greater thickness than the first portion and extends from the first portion, and the second portion may be inserted into the hole of the bump.

The electronic device may further include an adhesive layer configured to couple the display panel and the electronic component. The insulating pattern and the bump may be spaced apart from each other, and the adhesive layer may fill a separation space between the insulating pattern and the bump.

The adhesive layer may include an acrylic resin.

The display panel may further include at least one insulating layer between the end portion of the signal line and the first conductive pattern, and the first conductive pattern may be electrically connected to the end portion of the signal line through a contact hole defined by the at least one insulating layer.

The signal pad may extend in one direction on a plane, the insulating pattern may include a plurality of insulating patterns, and the plurality of insulating patterns may be spaced apart from one another in the one direction.

A gap between two insulating patterns adjacent to each other among the plurality of insulating patterns may range from 8 μm to 12 μm.

The display panel may further include at least one insulating layer between the end portion of the signal line and the first conductive pattern. The end portion of the signal line and the first conductive pattern may be connected through a plurality of contact holes defined by the at least one insulating layer. The plurality of contact holes and the plurality of insulating patterns may alternate with one another in the one direction.

The hole may include a plurality of holes on a plane and the second metal line portion include a plurality of second metal line portions on the plane. The plurality of holes may be spaced apart from one another in the one direction, and the plurality of the second metal line portions may be spaced apart from one another in the one direction. The plurality of holes may correspond to the plurality of the second metal line portions configured to protrude from the plurality of insulating patterns, respectively.

A length of the bump in the one direction may be longer than a length of the insulating pattern in the one direction.

The hole of the bump may have a depth of 2 μm to 4 μm.

Each of the first metal line portion and the second metal line portion may include a first layer, a second layer on the first layer, and a third layer that is on the second layer and that includes a same material as the first layer.

The insulating pattern may have a thickness greater than or equal to 2 μm and less than 4 μm.

According to some example embodiments, a display panel includes a pixel, a signal line electrically connected to the pixel, and a signal pad electrically connected with the signal line. The signal pad includes a first conductive pattern electrically connected to an end portion of the signal line, an insulating pattern on the first conductive pattern, and a second conductive pattern configured to contact the first conductive pattern and includes a first metal line portion configured to contact an outer surface of the insulating pattern and a second metal line portion configured to extend from the first metal line portion and protrude from the insulating pattern.

The first metal line portion may have a spiral shape.

The second metal line portion may include a first portion having a same thickness as the first metal line portion and a second portion that has a greater thickness than the first portion and extends from the first portion.

Each of the first metal line portion and the second metal line portion may include a first layer, a second layer on the first layer, and a third layer on the second layer and that includes a same material as the first layer.

The signal pad may extend in one direction on a plane. The insulating pattern may include a plurality of insulating patterns. The plurality of insulating patterns may be spaced apart from one another in the one direction. A gap between two insulating patterns adjacent to each other among the plurality of insulating patterns may range from 8 μm to 12 μm.

A gap between two insulating patterns adjacent to each other among the plurality of insulating patterns may range from 8 μm to 12 μm.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic device according to some example embodiments of the present disclosure.

FIG. 2 illustrates schematic views of electronic devices according to some example embodiments.

FIG. 3 is an assembled perspective view of an electronic device according to some example embodiments of the present disclosure.

FIG. 4 is an exploded perspective view of the electronic device according to some example embodiments of the present disclosure.

FIG. 5 is a sectional view of a display device according to some example embodiments of the present disclosure.

FIG. 6 is a plan view of a display panel according to some example embodiments of the present disclosure.

FIG. 7 is a sectional view of the display panel according to some example embodiments of the present disclosure.

FIG. 8 is an enlarged exploded perspective view of pad areas of the display device according to some example embodiments of the present disclosure.

FIG. 9A is an enlarged plan view of a signal pad according to some example embodiments of the present disclosure.

FIG. 9B is an enlarged plan view of a partial area of the signal pad according to some example embodiments of the present disclosure.

FIGS. 10A and 10B are sectional views of a pad area of the electronic device according to some example embodiments of the present disclosure.

FIGS. 11A and 11B are sectional views of portions of the electronic device to which a driver chip is bonded according to some example embodiments of the present disclosure.

FIGS. 12A to 12F are schematic sectional views illustrating steps of a bonding method of the electronic device according to some example embodiments of the present disclosure.

### DETAILED DESCRIPTION

In this specification, when a component (or an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component, part, area, layer, or portion from other components, parts, areas, layers, or portions. For example, without departing the scope and scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B. While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, example embodiments of the present disclosure will be described with reference to the accompanying drawings.

A display device according to some example embodiments may be applied to various electronic devices. An electronic device according to some example embodiments may include the display device described above and may further include modules or devices having other additional functions, in addition to the display device.

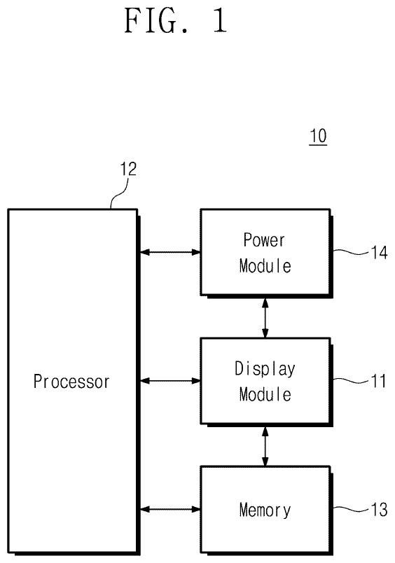

FIG. 1 is a block diagram of an electronic device according to some example embodiments of the present disclosure. Referring to FIG. 1, the electronic device 10 according to some example embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information required for operation of the processor 12 or the display module 11 may be stored in the memory 13. When the processor 12 executes an application stored in the memory 13, an image data signal and/or an input control signal may be transferred to the display module 11, and the display module 11 may process the received signal and may output image information through a display screen.

The power module 14 may include a power supply module, such as a power adaptor or a battery device, and a power conversion module that converts power supplied by the power supply module and generates power required for operation of the electronic device 10.

At least one of the components of the electronic device 10 described above may be included in the display device according to some example embodiments described above. In addition, some of the separate modules functionally included in one module may be included in the display device, and the others may be provided separately from the display device. For example, the display device may include the display module 11, and the processor 12, the memory 13, and the power module 14 may be provided in the form of other devices within the electronic device 10 rather than the display device.

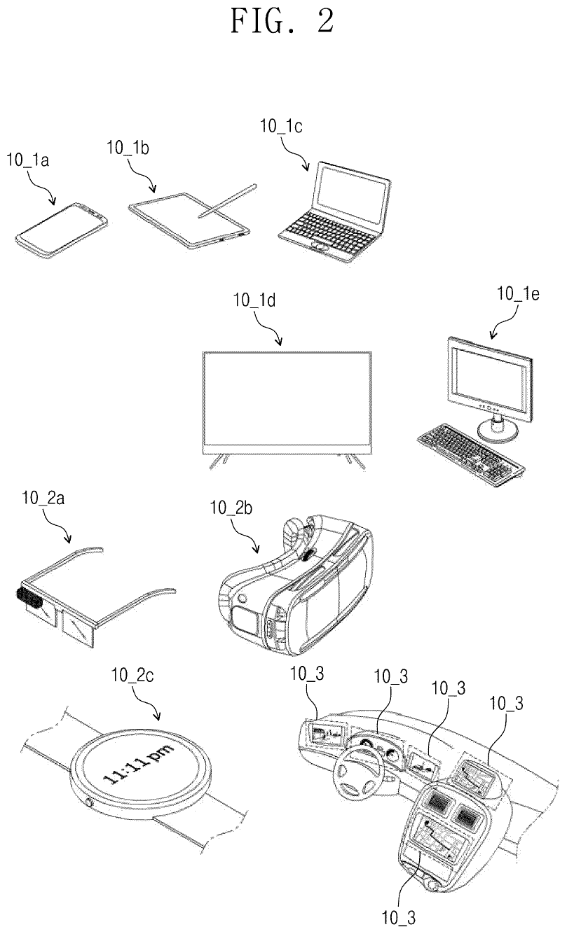

FIG. 2 illustrates schematic views of electronic devices according to some example embodiments.

Referring to FIG. 2, various electronic devices according to some example embodiments to which a display device is applied may include not only an electronic device for displaying an image, such as a smart phone 10_1a, a tablet PC 10_1b, a laptop computer 10_1c, a TV 10_1d, and/or a desk monitor 10_1e, but also a wearable electronic device, such as smart glasses 10_2a, a head mounted display 10_2b, and/or a smart watch 10_2c, which includes a display module, and a vehicle electronic device 10_3, such as a center information display (CID) disposed on an instrument panel, a center fascia, and a dashboard of a vehicle or a room mirror display, which includes a display module.

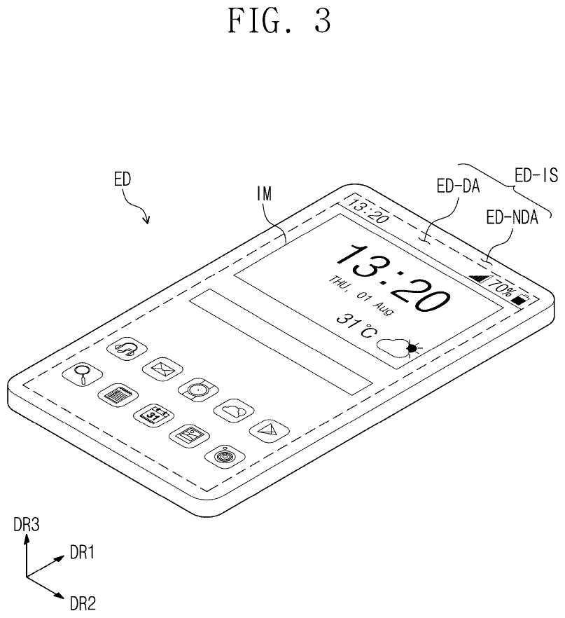

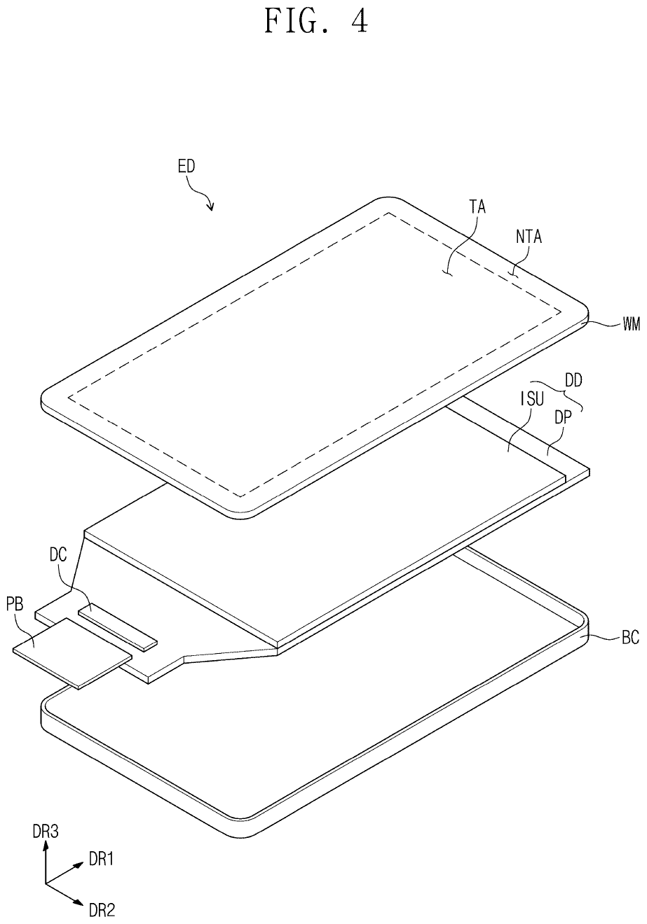

FIG. 3 is an assembled perspective view of an electronic device ED according to some example embodiments of the present disclosure. FIG. 4 is an exploded perspective view of the electronic device ED according to some example embodiments of the present disclosure.

In FIGS. 3 and 4, a smart phone is illustrated as an example of the electronic device ED. However, example embodiments are not limited thereto, and may be implemented in various electronic devices. Referring to FIG. 3, the electronic device ED may display an image IM through a display surface ED-IS. Icon images are illustrated as an example of the image IM. The display surface ED-IS is parallel to a plane defined by a first direction DR1 and a second direction DR2. The normal direction of the display surface ED-IS, that is, the thickness direction of the electronic device ED is indicated by a third direction DR3. The expression “when viewed from above the plane or on the plane” used herein may mean that it is viewed in the third direction DR3. Front surfaces (or upper surfaces) and rear surfaces (or lower surfaces) of layers or units to be described below are distinguished from each other based on the third direction DR3.

The display surface ED-IS includes a display area ED-DA where the image IM is displayed and a non-display area ED-NDA adjacent to the display area ED-DA. The non-display area ED-NDA is an area where no image is displayed. However, without being limited thereto, the non-display area ED-NDA may be adjacent to one side of the display area ED-DA or may be omitted. For example, the display surface ED-IS may be defined by the non-display area ED-NDA, a boundary of the electronic device, or both.

Referring to FIG. 4, the electronic device ED may include a window WM, a display device DD, and a housing BC. The housing BC may accommodate the display device DD and may be coupled with the window WM. Although not illustrated, the electronic device ED may further include other electronic modules accommodated in the housing BC and electrically connected with a display panel DP. For example, the electronic device ED may further include a main board, and a circuit module, a camera module, and/or a power module mounted on the main board.

The window WM may be disposed on the display device DD and may transmit an image provided from the display device DD to the outside. The window WM may include a transmissive area TA and a non-transmissive area NTA. The transmissive area TA may overlap the display area ED-DA of FIG. 3 and may have a shape corresponding to the display area ED-DA.

The non-transmissive area NTA may overlap the non-display area ED-NDA (refer to FIG. 3) and may have a shape corresponding to the non-display area ED-NDA (refer to FIG. 3). The non-transmissive area NTA may be an area having a lower light transmittance than the transmissive area TA.

The display device DD may generate an image and may sense an external input. The display device DD may include the display panel DP and an input sensor ISU. Although not illustrated, the display device DD may further include an anti-reflective member disposed on the input sensor ISU. The anti-reflective member may include a polarizer and a retarder or may include a color filter and a black matrix.

According to some example embodiments of the present disclosure, the display panel DP may be an emissive display panel, and the type thereof is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include a quantum dot, a quantum rod, and/or a nano-LED. Hereinafter, the display panel DP will be described as an organic light emitting display panel.

The input sensor ISU may include one of a capacitive sensor, an optical sensor, an ultrasonic sensor, and an electromagnetic induction sensor. The input sensor ISU may be formed on the display panel DP through a continuous process or may be manufactured separately from the display panel DP and then attached to the upper side of the display panel DP through an adhesive layer or other means.

The display device DD of some example embodiments may further include a driver chip DC and a circuit board PB. Although FIG. 4 illustrates some example embodiments in which the driver chip DC is mounted on the display panel DP, the present disclosure is not limited thereto. The driver chip DC may generate a driving signal required for operation of the display panel DP, based on a control signal transferred from the circuit board PB. The circuit board PB bonded to the display panel DP may be bent and disposed on the rear surface of the display panel DP. The circuit board PB may be disposed at one end of a base layer to be described below and may be electrically connected to a circuit element layer to be described below.

In the display device DD of some example embodiments, a portion of the display panel DP may be bent such that the driver chip DC faces downward. A portion of the non-display area ED-NDA (refer to FIG. 3) of the display panel DP may be bent. However, a portion to be bent is not limited thereto, and the circuit board PB may be bent.

Although the smart phone has been described as an example of the electronic device ED, it is sufficient that the electronic device ED includes two or more bonded electronic components in this specification. The display panel DP and the driver chip DC mounted on the display panel DP may correspond to different electronic components, respectively, and the electronic device ED may be constituted by only the display panel DP and the driver chip DC. Alternatively, the electronic device ED may be constituted by only the display panel DP and the circuit board PB connected to the display panel DP. In another case, the electronic device ED may be constituted by only the main board and electronic modules mounted on the main board. Hereinafter, the display device DD and the electronic device ED according to the present disclosure will be described focusing on a bonding structure of the display panel DP and the driver chip DC mounted on the display panel DP.

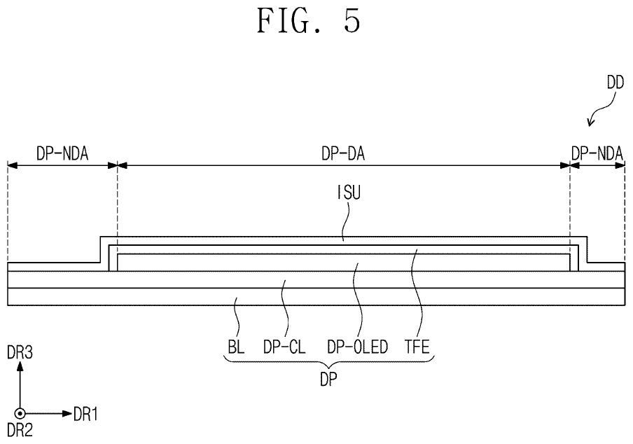

FIG. 5 is a sectional view of the display device DD according to some example embodiments of the present disclosure.

Referring to FIG. 5, the display panel DP may include the base layer BL, and the circuit element layer DP-CL, a display element layer DP-OLED, and a thin film encapsulation layer TFE that are disposed on the base layer BL. That is, the base layer BL, the circuit element layer DP-CL, the display element layer DP-OLED, and the thin film encapsulation layer TFE may be stacked sequentially in the third direction DR3. The input sensor ISU may be disposed on the thin film encapsulation layer TFE.

The display panel DP may include a display area DP-DA and a non-display area DP-NDA. The display area DP-DA of the display panel DP is defined by and/or corresponds to the display area ED-DA illustrated in FIG. 3 or the transmissive area TA illustrated in FIG. 4, and the non-display area DP-NDA is defined by and/or corresponds to the non-display area ED-NDA illustrated in FIG. 3 or the non-transmissive area NTA illustrated in FIG. 4. For example, the display area DP-DA may be defined by the non-display area DP-NDA, a boundary of the display panel DP, or both.

The base layer BL may include the display area DP-DA and the non-display area DP-NDA around the display area DP-DA. The base layer BL may include a synthetic resin film. The base layer BL may have a multi-layer structure. For example, the base layer BL may have a three-layer structure including a synthetic resin layer, an inorganic layer, and a synthetic resin layer. In particular, the synthetic resin layers may be polyimide-based resin layers, and the materials thereof are not particularly limited. The synthetic resin layers may include at least one of an acrylic resin, a methacrylic resin, a polyisoprene resin, a vinyl resin, an epoxy resin, a urethane-based resin, a cellulosic resin, a siloxane-based resin, a polyamide resin, or a perylene-based resin. In addition, the base layer BL may include a glass substrate, a metal substrate, or an organic/inorganic composite substrate.

The circuit element layer DP-CL may include at least one insulating layer and a circuit element. The insulating layer may include at least one inorganic layer and at least one organic layer. The circuit element may include signal lines and a pixel driving circuit. An insulating layer, a semiconductor layer, and a conductive layer are formed through a process such as coating, deposition, and/or the like. Thereafter, the insulating layer, the semiconductor layer, and the conductive layer may be selectively subjected to patterning through a photolithography process and an etching process. A semiconductor pattern, a conductive pattern, and a signal line are formed through these processes. Patterns disposed on the same layer are formed through the same process. Hereinafter, when patterns are formed through the same process, this means that the patterns include the same material and have the same stack structure.

The display element layer DP-OLED may include an organic light emitting element. The display element layer DP-OLED may further include an organic layer such as a pixel defining layer.

The thin film encapsulation layer TFE may be disposed on the circuit element layer DP-CL to cover the display element layer DP-OLED. The thin film encapsulation layer TFE may protect pixels from moisture, oxygen, and external foreign matter. However, without being limited thereto, the thin film encapsulation layer TFE may further include an additional insulating layer. For example, the thin film encapsulation layer TFE may further include an optical insulating layer for controlling a refractive index.

The input sensor ISU may be directly disposed on the display panel DP. The input sensor ISU may be manufactured together with the display panel DP through a continuous process. However, the spirit and scope of the present disclosure is not limited thereto, and the input sensor ISU may be provided as a separate panel and may be coupled with the display panel DP through an adhesive layer. According to some example embodiments, the input sensor ISU may be omitted.

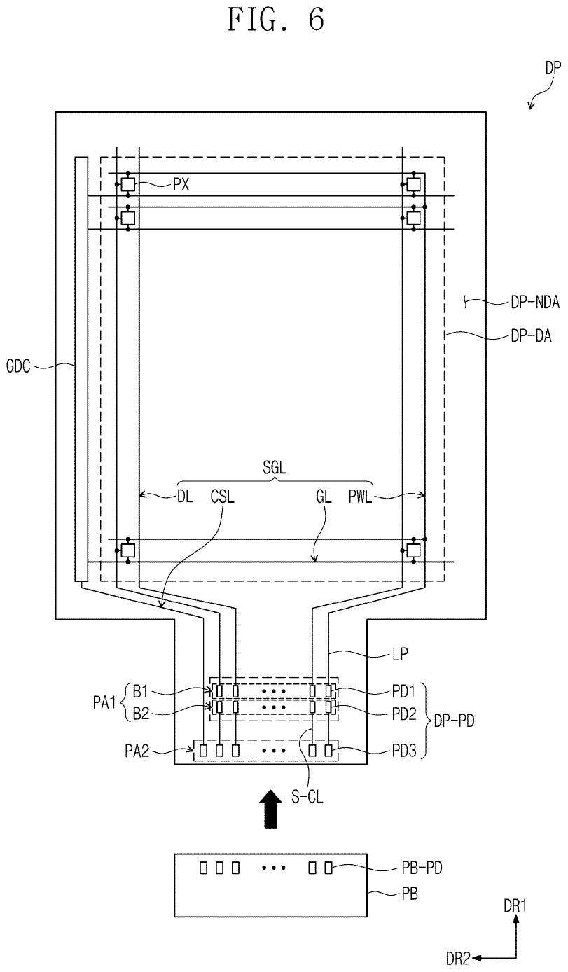

FIG. 6 is a plan view of the display panel DP according to some example embodiments of the present disclosure. FIG. 6 illustrates the planar shape of the display panel DP illustrated in FIG. 5.

Referring to FIG. 6, the display panel DP may include a plurality of pixels PX, a gate driver circuit GDC, a plurality of signal lines SGL, and a plurality of signal pads DP-PD.

The pixels PX are disposed in the display area DP-DA. Each of the pixels PX may include a light emitting element and a pixel driving circuit connected thereto. The gate driver circuit GDC sequentially outputs gate signals to a plurality of gate lines GL to be described below. A transistor of the gate driver circuit GDC and a transistor of the pixel PX may be formed through the same process, for example, a low-temperature polycrystalline silicon (LTPS) process or a low-temperature polycrystalline oxide (LTPO) process. The display panel DP may further include another driver circuit that provides emission control signals to the pixels PX.

The signal lines SGL may include the gate lines GL, data lines DL, a power line PWL, and a control signal line CSL. Each of the gate lines GL is connected to a corresponding one of the pixels PX, and each of the data lines DL is connected to a corresponding one of the pixels PX. The power line PWL is connected to the pixels PX. The control signal line CSL may be connected to the gate driver circuit GDC and may provide control signals to the gate driver circuit GDC.

The signal lines SGL may overlap the display area DP-DA and the non-display area DP-NDA. Each of the signal lines SGL may include a line portion LP. The line portion LP may overlap the display area DP-DA and the non-display area DP-NDA.

The plurality of signal pads DP-PD may include first pads PD1, second pads PD2, and third pads PD3. The area where the first pads PD1 and the second pads PD2 are disposed may be defined as a first pad area PA1, and the area where the third pads PD3 are disposed may be defined as a second pad area PA2.

The first pad area PA1 is an area bonded with the driver chip DC (refer to FIG. 4), and the second pad area PA2 is an area bonded with the circuit board PB (refer to FIG. 4). The first pad area PA1 may include a first area B1 where the first pads PD1 are disposed and a second area B2 where the second pads PD2 are disposed. The first pad area PA1 and the second pad area PA2 may be disposed in the non-display area DP-NDA. The first pad area PA1 and the second pad area PA2 may be spaced apart from each other in the first direction DR1. The first pad area PA1 may be an area closer to the display area DP-DA than the second pad area PA2, and the second pad area PA2 may be an area spaced apart from the display area DP-DA with the first pad area PA1 therebetween.

Each of the first pads PD1 may be connected to a corresponding one of the data lines DL. Although not illustrated, the first pads PD1 and the second pads PD2 may be electrically connected with each other. The second pads PD2 may be connected with the third pads PD3 through connecting signal lines S-CL.

The circuit board PB may include a plurality of circuit pads PB-PD. The circuit pads PB-PD may be arranged in the second direction DR2. The circuit pads PB-PD of the circuit board PB may be connected with the third pads PD3 in the second pad area PA2 by making contact with the third pads PD3 (e.g., the circuit pads PB-PD may be configured to contact the third pads PD3).

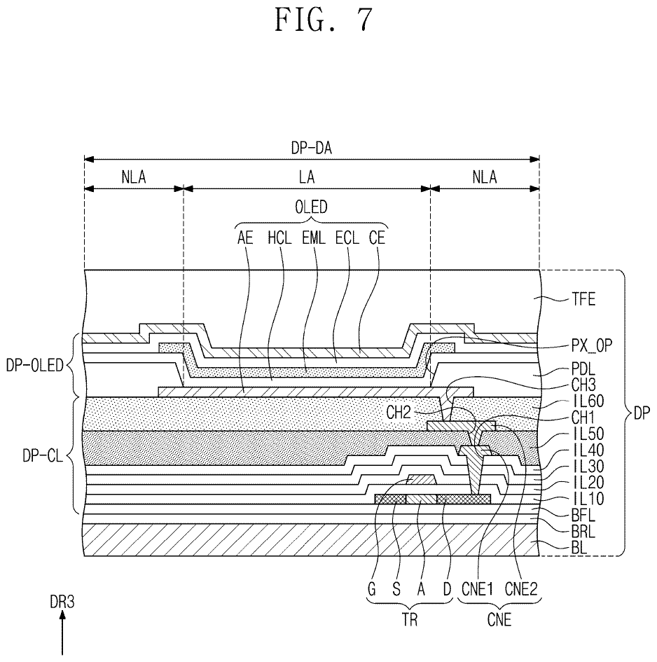

FIG. 7 is a sectional view of the display panel DP according to some example embodiments of the present disclosure.

Referring to FIG. 7, the display panel DP may include the base layer BL, and the circuit element layer DP-CL, the display element layer DP-OLED, and the thin film encapsulation layer TFE that are disposed on the base layer BL.

A plurality of insulating layers are disposed on the upper surface of the base layer BL. The plurality of insulating layers may include a barrier layer BRL and a buffer layer BFL. The plurality of insulating layers may further include first to sixth insulating layers IL10 to IL60. The barrier layer BRL prevents or reduces infiltration of foreign matter from the outside. The barrier layer BRL may include a silicon oxide layer and a silicon nitride layer. In some example embodiments, a plurality of silicon oxide layers and a plurality of silicon nitride layers may be provided. The silicon oxide layers and the silicon nitride layers may be alternately stacked one above another.

The buffer layer BFL improves the coupling force between the base layer BL and a semiconductor pattern and/or a conductive pattern. The buffer layer BFL may include silicon oxide layers and silicon nitride layers. The silicon oxide layers and the silicon nitride layers may be alternately stacked one above another.

The semiconductor pattern may be disposed on the buffer layer BFL. The semiconductor pattern may include poly silicon. The semiconductor pattern may include an amorphous or polycrystalline silicon semiconductor or a metal oxide semiconductor. Meanwhile, a portion of the semiconductor pattern is illustrated in FIG. 7, and the semiconductor pattern may be additionally disposed in other areas of the display panel DP when viewed from above the plane. The semiconductor pattern may be doped with an N-type dopant or a P-type dopant. The semiconductor pattern may include highly-doped areas and a lightly-doped area. The highly-doped areas may have a higher conductivity than the lightly-doped area and may serve or substantially serve as a source electrode and a drain electrode of a transistor TR. The lightly doped area may correspond or substantially correspond to an active (or channel) area of the transistor TR.

The drain D, the active area A, and the source S may be disposed on the buffer layer BFL. The drain D, the active area A, and the source S may define the transistor TR together with a gate G to be described below. When the display panel DP includes a transistor other than the transistor TR, the transistor may include a material different from that of the transistor TR and may be disposed in a layer different from the layer in which the transistor TR is disposed. The source S, the active area A, and the drain D of the transistor TR may be formed from the semiconductor pattern.

The first insulating layer IL10 may be disposed on the buffer layer BFL. The first insulating layer IL10 may cover the semiconductor pattern. The gate G of the transistor TR may be disposed on the first insulating layer IL10. The second insulating layer IL20 may be disposed on the gate G. The gate G may be a portion of a metal pattern. The gate G may overlap the active area A. The gate G may function as a mask in a process of doping the semiconductor pattern.

The gate G may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), and/or indium zinc oxide (IZO), but is not particularly limited thereto.

The second insulating layer IL20 may be disposed on the first insulating layer IL10 to cover the gate G. The transistor TR according to some example embodiments may further include an upper electrode that is disposed on the second insulating layer IL20 and that overlaps the gate G. The third insulating layer IL30 may be disposed on the second insulating layer IL20. The fourth insulating layer IL40 may be disposed on the third insulating layer IL30. The first to fourth insulating layers IL10 to IL40 may be inorganic layers and/or organic layers and may have a single-layer structure or a multi-layer structure.

A connecting electrode CNE may include a first connecting electrode CNE1 and a second connecting electrode CNE2 to connect the transistor TR and a light emitting element OLED. The first connecting electrode CNE1 may be disposed on the fourth insulating layer IL40 and may be connected to the drain D through a first contact hole CH1 defined by the first to fourth insulating layers IL10 to IL40.

The fifth insulating layer IL50 may be disposed on the fourth insulating layer IL40. The fifth insulating layer IL50 may be an organic layer. The second connecting electrode CNE2 may be disposed on the fifth insulating layer IL50. The second connecting electrode CNE2 may be connected to the first connecting electrode CNE1 through a second contact hole CH2 defined by the fifth insulating layer IL50.

The sixth insulating layer IL60 may be disposed on the second connecting electrode CNE2. The layers from the buffer layer BFL to the sixth insulating layer IL60 may be defined as the circuit element layer DP-CL. The sixth insulating layer IL60 may be an organic layer. A first electrode AE may be disposed on the sixth insulating layer IL60. The first electrode AE may be connected to the second connecting electrode CNE2 through a third contact hole CH3 defined by the sixth insulating layer IL60. The first electrode AE may be connected to the transistor TR through the first connecting electrode CNE1 and the second connecting electrode CNE2. A pixel defining layer PDL having an opening PX_OP defined therein to expose a certain portion of the first electrode AE may be disposed on the first electrode AE and the sixth insulating layer IL60.

A hole control layer HCL may be disposed on the first electrode AE and the pixel defining layer PDL. The hole control layer HCL may include a hole transport layer and a hole injection layer.

An emissive layer EML may be disposed on the hole control layer HCL. The emissive layer EML may be disposed in an area corresponding to the opening PX_OP. The emissive layer EML may include an organic material and/or an inorganic material. The emissive layer EML may generate one of red light, green light, and blue light.

An electron control layer ECL may be disposed on the emissive layer EML and the hole control layer HCL. The electron control layer ECL may include an electron transport layer and an electron injection layer. The hole control layer HCL and the electron control layer ECL may be commonly disposed in an emissive area LA and a non-emissive area NLA.

A second electrode CE may be disposed on the electron control layer ECL. The second electrode CE may be commonly disposed in the pixels PX (refer to FIG. 6). The layer in which the light emitting element OLED is disposed may be defined as the display element layer DP-OLED.

The thin film encapsulation layer TFE may be disposed on the second electrode CE and may cover the pixels PX (refer to FIG. 6). Although not illustrated, the thin film encapsulation layer TFE may include a plurality of layers. Some of the plurality of layers may include an inorganic layer and may protect the pixels PX (refer to FIG. 6) from moisture and/or oxygen. The other layers may include an organic layer and may protect the pixels PX (refer to FIG. 6) from foreign matter such as dust particles.

A first voltage may be applied to the first electrode AE through the transistor TR, and a second voltage having a lower level than the first voltage may be applied to the second electrode CE. Holes and electrons injected into the emissive layer EML may be combined to form excitons, and as the excitons transition to a ground state, the light emitting element OLED may emit light.

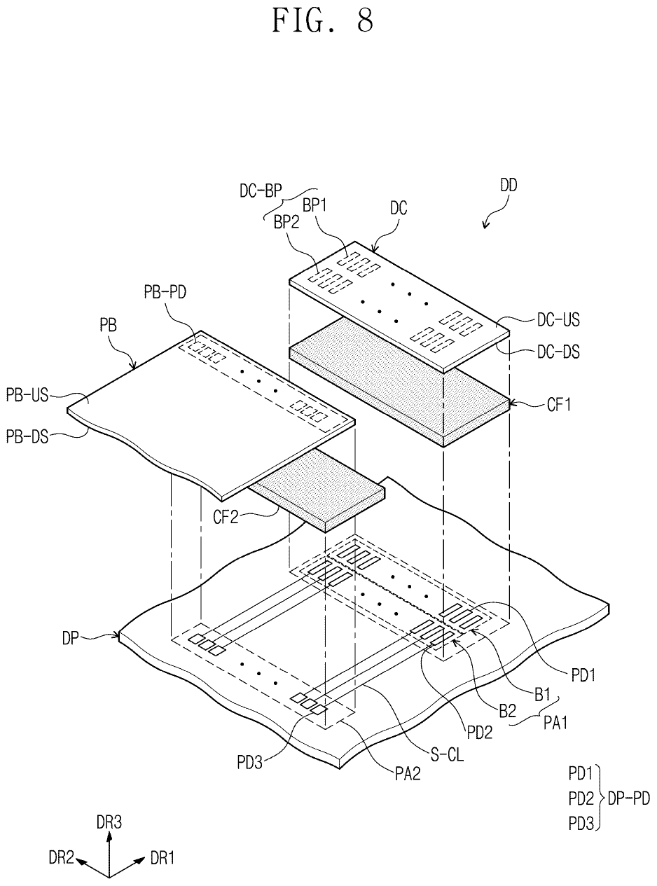

FIG. 8 is an enlarged exploded perspective view of the pad areas PA1 and PA2 of the display device DD according to some example embodiments of the present disclosure. For example, in FIG. 8, the driver chip DC and the circuit board PB are illustrated as being disassembled from the display panel DP. The first pads PD1, the second pads PD2, the connecting signal lines S-CL, and the third pads PD3 of FIG. 8 are identical to those illustrated in FIG. 6, and therefore detailed description thereof will be omitted.

The driver chip DC may be bonded to the first pad area PA1 through a first adhesive layer CF1, and the circuit board PB may be bonded to the second pad area PA2 through a second adhesive layer CF2.

According to some example embodiments of the present disclosure, the first adhesive layer CF1 and the second adhesive layer CF2 may be non-conductive films. The first adhesive layer CF1 and the second adhesive layer CF2 may not include conductive balls and may include an adhesive synthetic resin.

In some example embodiments, the first adhesive layer CF1 and the second adhesive layer CF2 may include an acrylic resin. For example, the acrylic resin may include at least one of acrylic oligomer, isobornyl acrylate, n-lauryl acrylate, or dipentaerythritol acrylate. The acrylic resin may have chemical resistance and UV curability and may fix pads and bumps to be described below in a contact state.

When the first adhesive layer CF1 is cured, the first pads PD1 and first bumps BP1 may be fixed in contact with each other, and the second pads PD2 and second bumps BP2 may be fixed in contact with each other. In addition, when the second adhesive layer CF2 is cured, the third pads PD3 and third bumps BP3 may be fixed in contact with each other.

The driver chip DC may include a driver integrated circuit and driving bumps DC-BP mounted in the driver chip DC. The driver chip DC may include an upper surface DC-US and a lower surface DC-DS, and the lower surface DC-DS may be a surface that faces the first pads PD1 and the second pads PD2. The driving bumps DC-BP may be disposed on the lower surface DC-DS of the driver chip DC.

The driving bumps DC-BP may include first bumps BP1 electrically connected to the first pads PD1, respectively, and second bumps BP2 electrically connected to the second pads PD2, respectively. The first bumps BP1 may be arranged in the second direction DR2, and the second bumps BP2 may be spaced apart from the first bumps BP1 in the first direction DR1 and may be arranged in the second direction DR2.

The driver chip DC may receive first signals from the outside through the second pads PD2 and the second bumps BP2. The driver chip DC may provide second signals generated based on the first signals to the first pads PD1 through the first bumps BP1. For example, the driver chip DC may include a data driver circuit. The first signals may be image signals that are digital signals applied from the outside, and the second signals may be data signals that are analog signals. The driver chip DC may generate analog voltages corresponding to grayscale values of the image signals. The data signals may be provided to the pixels PX through the data lines DL illustrated in FIG. 6.

In FIG. 8, for convenience of description, the planar shapes of the driving bumps DC-BP are illustrated by dotted lines on the upper surface DC-US of the driver chip DC. However, each of the first bumps BP1 and the second bumps BP2 may protrude from the lower surface DC-DS of the driver chip DC and may have a shape exposed to the outside.

The circuit board PB may be disposed on the display panel DP. The circuit board PB may be disposed on the third pads PD3. The circuit board PB may include an upper surface PB-US and a lower surface PB-DS, and the lower surface PB-DS may be a surface facing the third pads PD3. The circuit board PB may include a plurality of circuit pads PB-PD electrically connected with the third pads PD3. The circuit pads PB-PD may be disposed on the upper surface PB-US of the circuit board PB. The circuit pads PB-PD may be arranged in the second direction DR2. The circuit board PB may provide the image signals, the driving voltages, and other control signals to the driver chip DC.

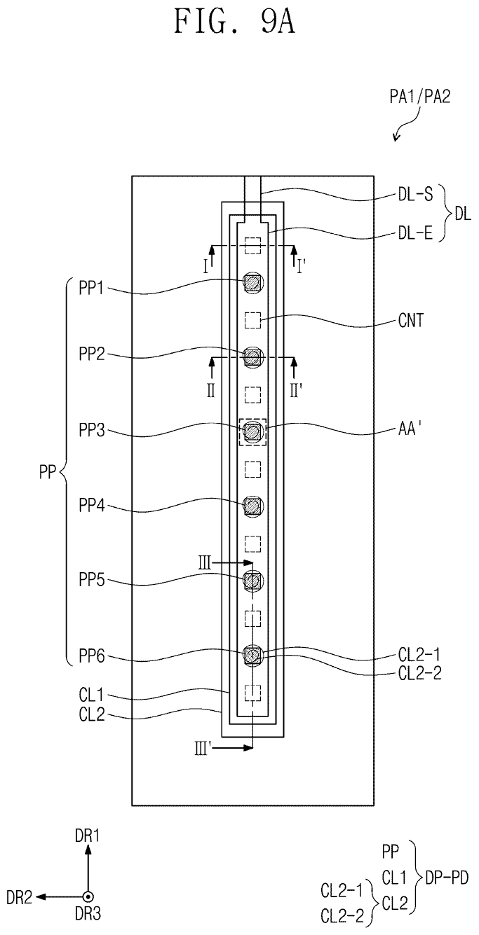

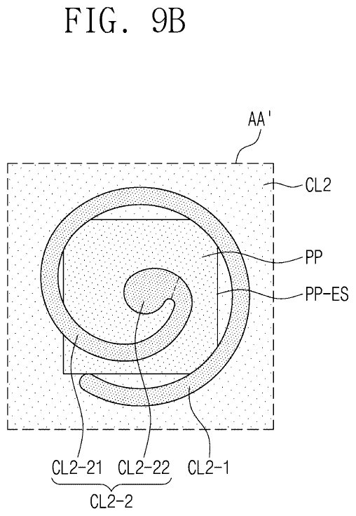

FIG. 9A is an enlarged plan view of a signal pad DP-PD according to some example embodiments of the present disclosure. FIG. 9B is an enlarged plan view of a partial area of the signal pad DP-PD according to some example embodiments of the present disclosure. FIG. 9A is an enlarged plan view illustrating the first pad area PA1 and the second pad area PA2 of the display panel DP and illustrates an example of one signal pad DP-PD. FIG. 9B is an enlarged plan view of a partial area AA′ of FIG. 9A.

In FIG. 9A, a data line DL including an end portion DL-E is illustrated as an example of the signal lines SGL (refer to FIG. 6). Although the data line DL including the end portion DL-E and a line portion DL-S having different widths is illustrated as an example of a signal line in FIG. 9A, the present disclosure is not limited thereto. The signal line may be a signal line other than the data line DL, and the end portion DL-E and the line portion DL-S may have a uniform width.

Hereinafter, the pad areas PA1 and PA2 will be described focusing on the first pad area PA1 where the data line DL is disposed. The second pad area PA2 is similar to the first pad area PA1, except the second pad area PA2 includes the connecting signal line S-CL (refer to FIG. 8) instead of the data line DL.

Referring to FIG. 9A, the signal pad DP-PD includes a first conductive pattern CL1 electrically connected to the end portion DL-E of the data line DL through at least one contact hole CNT, insulating patterns PP disposed on the first conductive pattern CL1, and a second conductive pattern CL2 making contact with the first conductive pattern CL1.

In the plan view of FIG. 9A, the signal pad DP-PD may extend in the first direction DR1, and the plurality of insulating patterns PP may be provided. Although FIG. 9A illustrates an example that one signal pad DP-PD includes six insulating pattern PP1 to PP6, the number of insulating patterns PP is not limited thereto. The insulating patterns PP may overlap the first conductive pattern CL1. The insulating patterns PP may be arranged in the first direction DR1. The insulating patterns PP may be spaced apart from one another in the first direction DR1.

In some example embodiments, the insulating patterns PP may include a polymer. The insulating patterns PP may include a thermosetting polymer. However, without being limited thereto, the insulating patterns PP may include a thermoplastic polymer.

Although the insulating patterns PP are illustrated as having a square shape when viewed from above the plane, the present disclosure is not limited thereto. For example, the planar shape of the insulating patterns PP may be changed to a rectangular shape, a polygonal shape other than a quadrangular shape, a circular shape, or an oval shape. In addition, the insulating patterns PP are not limited to having the same shape.

Referring to FIG. 9A, a plurality of contact holes CNT may be provided. The plurality of contact holes CNT may be arranged in the first direction DR1. The plurality of contact holes CNT may be spaced apart from one another in the first direction DR1.

In some example embodiments, the plurality of contact holes CNT and the plurality of insulating patterns PP may alternate with one another in the first direction DR1. That is, one contact hole CNT may be located between two insulating patterns PP adjacent to each other.

In some example embodiments, the gap between two insulating patterns adjacent to each other among the insulating patterns PP may range from about or exactly 8 μm to about or exactly 12 μm. The insulating patterns PP may need to have a sufficient gap therebetween to alternate with the contact holes CNT electrically connected with the end portion DL-E of the data line DL.

The first conductive pattern CL1 may be disposed inside the second conductive pattern CL2 when viewed from above the plane. An additional conductive pattern may be further included in addition to the second conductive pattern CL2, and the present disclosure is not limited thereto.

As illustrated in FIG. 9B, the second conductive pattern CL2 includes a first metal line portion CL2-1 making contact with an outer surface PP-ES of the insulating pattern PP and a second metal line portion CL2-2 extending from the first metal line portion CL2-1 and protruding from the insulating pattern PP.

In some example embodiments, the first metal line portion CL2-1 may have a spiral shape. That is, the first metal line portion CL2-1 may have a shape spiraling upward along a portion of the outer surface PP-ES of the insulating pattern PP. The first metal line portion CL2-1 may completely spiral upward along the entire outer surface PP-ES of the insulating pattern PP or may spiral upward along a portion of the outer surface PP-ED of the insulating pattern PP. For example, the spiral may be a curve which emanates from a point (such as the second portion CL2-22), moving further away as it revolves around the point.

The second metal line portion CL2-2 may include a first portion CL2-21 having the same or similar thickness (along a plane in the first and second directions DR1 and DR2) as that of the first metal line portion CL2-1 and a second portion CL2-22 extending from the first portion CL2-21 and having a thickness greater than the thickness of the first portion CL2-21. The second portion CL2-22 may be defined relative to the first portion CL2-21 by the change in thickness, and the second portion CL2-22 may have a circular shape in plan view, however, examples embodiments are not limited thereto. The second portion CL2-22 may contact or substantially make contact with the driving bumps DC-BP (refer to FIG. 8). The second portion CL2-22 may protrude in the third direction DR3 and may have a greater thickness than that of the first portion CL2-21, and thus the contact area with the driving bumps DC-BP (refer to FIG. 8) may be increased.

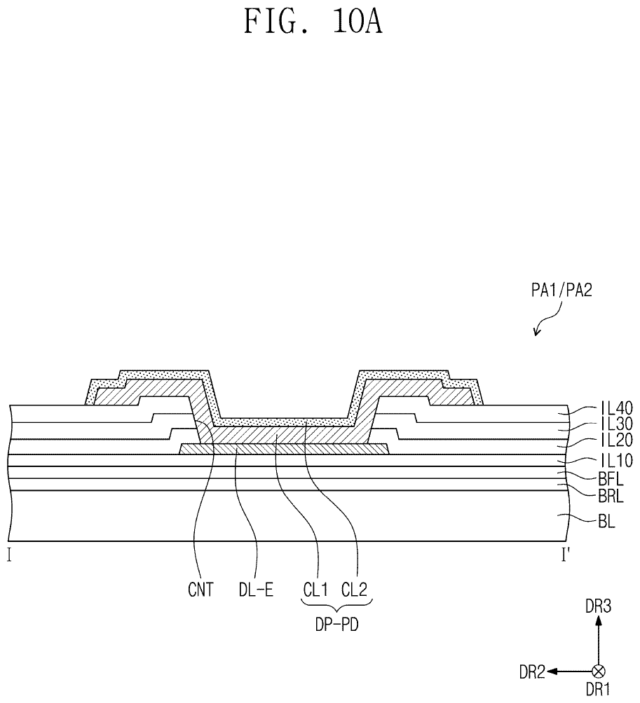

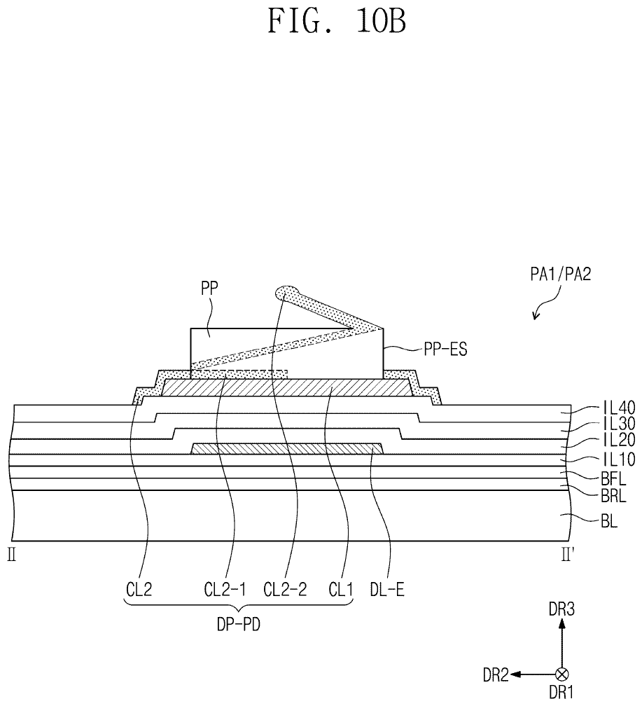

FIGS. 10A and 10B are sectional views of a pad area of the electronic device according to some example embodiments of the present disclosure. FIG. 10A is a sectional view corresponding to line I-I′ of FIG. 9A, and FIG. 10B is a sectional view corresponding to line II-II′ of FIG. 9A. Detailed description of components identical to the components described with reference to FIG. 7 may be referred to by the above description in relation to FIG. 7.

As illustrated in FIGS. 10A and 10B, the end portion DL-E of the data line (hereinafter, referred to as the end portion) may be disposed on the first insulating layer IL10. The end portion DL-E may be disposed on the same layer as the gate G (refer to FIG. 7). The end portion DL-E may be formed through the same process as the gate G (refer to FIG. 7) and may include the same material as the gate G (refer to FIG. 7). However, the position of the end portion DL-E is not limited thereto. Some of the plurality of signal lines may be disposed on the same layer as the gate G (refer to FIG. 7), and the others may be disposed on the second insulating layer IL20.

The first conductive pattern CL1 may be disposed on the fourth insulating layer IL40. The first conductive pattern CL1 may be electrically connected to the end portion DL-E through a contact hole CNT that penetrates the second to fourth insulating layers IL20, IL30, and IL40. That is, the first conductive pattern CL1 may be brought into contact with the end portion DL-E through the contact hole CNT. The second to fourth insulating layers IL20, IL30, and IL40 may be formed through the same process as the second to fourth insulating layers IL20, IL30, and IL40 in the display area DP-DA illustrated in FIG. 7.

The second conductive pattern CL2 may be disposed on the first conductive pattern CL1. The areas of the second conductive pattern CL2 that do not overlap the insulating pattern PP may make contact with the first conductive pattern CL1.

In some example embodiments, the first conductive pattern CL1 may be formed through the same process as the first connecting electrode CNE1 described above with reference to FIG. 7, and the second conductive pattern CL2 may be formed through the same process as the second connecting electrode CNE2 described above with reference to FIG. 7. The first conductive pattern CL1 may include the same material as the first connecting electrode CNE1 (refer to FIG. 7), and the second conductive pattern CL2 may include the same material as the second connecting electrode CNE2 (refer to FIG. 7).

Referring to FIG. 10B, the first metal line portion CL2-1 may make contact with the outer surface PP-ES of the insulating pattern PP, and the second metal line portion CL2-2 may extend from the first metal line portion CL2-1 and may protrude from the insulating pattern PP. The second metal line portion CL2-2 may overlap the insulating pattern PP.

In some example embodiments, the first metal line portion CL2-1 and the second metal line portion CL2-2 may be formed through the same process. That is, the first metal line portion CL2-1 and the second metal line portion CL2-2 may include the same material. The second conductive pattern CL2 making contact with the first conductive pattern CL1 may include the same material as the first metal line portion CL2-1 and the second metal line portion CL2-2, but is not necessarily limited thereto. The second conductive pattern CL2 may be formed through a separate process from the first metal line portion CL2-1 and the second metal line portion CL2-2. For example, the first metal line portion CL2-1 and the second metal line portion CL2-2 may have a spiral shape formed by winding the insulating pattern PP upward through a separate process. Thereafter, the second conductive pattern CL2 disposed on the first conductive pattern CL1 may be formed through an additional deposition process.

In some example embodiments, the first metal line portion CL2-1 and the second metal line portion CL2-2 may include a first layer, a second layer, and a third layer sequentially stacked one above another. The second layer may be disposed on the first layer, and the third layer may be disposed on the second layer. The third layer may include the same material as the first layer. For example, the first layer and the third layer may include titanium (Ti), and the second layer may include aluminum. The second layer may have a greater thickness than the first layer and the third layer and may be covered by the third layer. Accordingly, oxidation and corrosion may be prevented, and thus the durability of the signal pad DP-PD may be improved. In addition, the second conductive pattern CL2 making contact with the first conductive pattern CL1 may have a stack structure that is the same as the stack structure of the first metal line portion CL2-1 and the second metal line portion CL2-2.

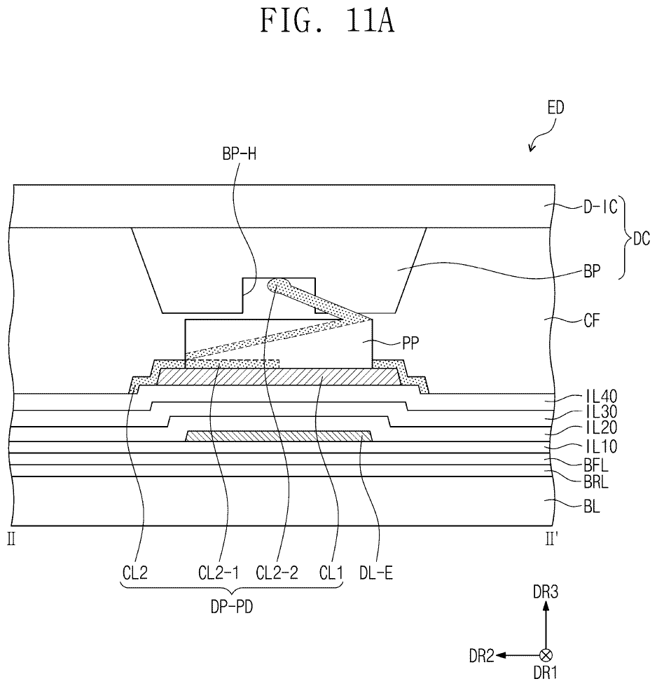

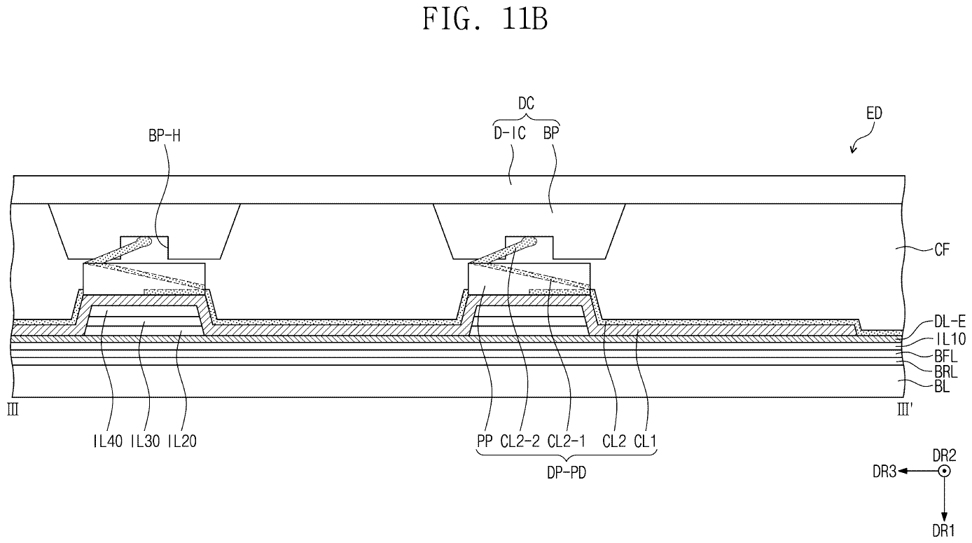

FIGS. 11A and 11B are sectional views of portions of the electronic device ED to which the driver chip DC is bonded according to some example embodiments of the present disclosure. FIG. 11A is a sectional view of the electronic device ED corresponding to line II-II′ of FIG. 9A, and FIG. 11B is a sectional view of the electronic device ED corresponding to line III-III′ of FIG. 9A. Detailed description of components identical to the components described with reference to FIGS. 10A and 10B may be referred to by the above description in relation to FIGS. 10A and 10B.

Referring to FIG. 11A, the driver chip DC may include a driver integrated circuit D-IC and a bump BP disposed on the lower surface of the driver chip DC. The bump BP may make contact with the second metal line portion CL2-2 and accordingly may be electrically connected with the signal pad DP-PD.

In some example embodiments of the present disclosure, a hole BP-H making contact with the second metal line portion CL2-2 is defined by the bump BP of the driver chip DC. The second portion CL2-22 (refer to FIG. 9B) of the second metal line portion CL2-2 may be inserted into the hole BP-H. That is, the second metal line portion CL2-2 may be inserted into the hole BP-H of the bump BP in a hook shape and may be brought into physical contact with the hole BP-H. Accordingly, electronic components may be bonded under temperature and pressure conditions relatively relaxed when compared to high-temperature and high-pressure conditions in a conventional bonding process, damage to the electronic components due to higher temperature may be alleviated, and cracks caused by higher pressure may be improved.

In some example embodiments, the hole BP-H of the bump BP may have a depth of about or exactly 2 μm to about or exactly 4 μm. The depth may mean the length of the hole BP-H in the third direction DR3. The second metal line portion CL2-2 may be inserted into the hole BP-H in a hook shape and may be physically coupled to the hole BP-H. Although the hole BP-H in FIG. 11B is illustrated as an opening having a rectangular shape, the shape of the hole BP-H is not limited thereto.

The electronic device ED may further include an adhesive layer CF that couples the pad part of the display panel and the driver chip DC. The insulating pattern PP and the driver chip DC may be spaced apart from each other, and the adhesive layer CF may fill the separation space. The adhesive layer CF may include an adhesive resin that covers the insulating pattern PP and the driver chip DC. For example, the adhesive layer CF may include an acrylic resin, and the driver chip DC and the signal pad DP-PD may be fixed in a contact state.

Referring to FIGS. 9A and 11B together, a plurality of insulating patterns PP may be provided in the first direction DR1 when viewed from above the plane. In some example embodiments, the hole BP-H of the bump BP may be provided in plural. The plurality of holes BP-H may be spaced apart from one another in the first direction DR1. The plurality of holes BP-H spaced apart from one another may correspond to the second metal line portions CL2-2 protruding from the plurality of insulating patterns PP, respectively. As the contact area between the signal pad DP-PD and the bump BP increases, contact resistance may be reduced, and bonding reliability may be improved.

In some example embodiments, the length of the bump BP in the first direction DR1 may be longer than the length of the insulating pattern PP in the first direction DR1. In a bonding process, a contact area between the second metal line portion CL2-2 protruding above the insulating pattern PP and the bump BP may be secured in consideration of a slight alignment error.

In some example embodiments, the insulating pattern PP may include a polymer. For example, the insulating pattern PP may include a photocurable resin or a thermosetting resin and may be cured by light or heat. The insulating pattern PP may have a thickness greater than or equal to about or exactly 2 μm and less than about or exactly 4 μm. The insulating pattern PP may be disposed on the first conductive pattern CL1 and may have a thickness in the third direction DR3 for contact with the bump BP. When the thickness of the insulating pattern PP is excessively large, the contact pressure between the bump BP and the signal pad DP-PD may increase to cause cracks. Accordingly, the insulating pattern PP may be spaced apart from the bump BP within the thickness range of the insulating pattern PP described above, and the second metal line portion CL2-2 may be physically coupled within the hole BP-H of the bump BP.

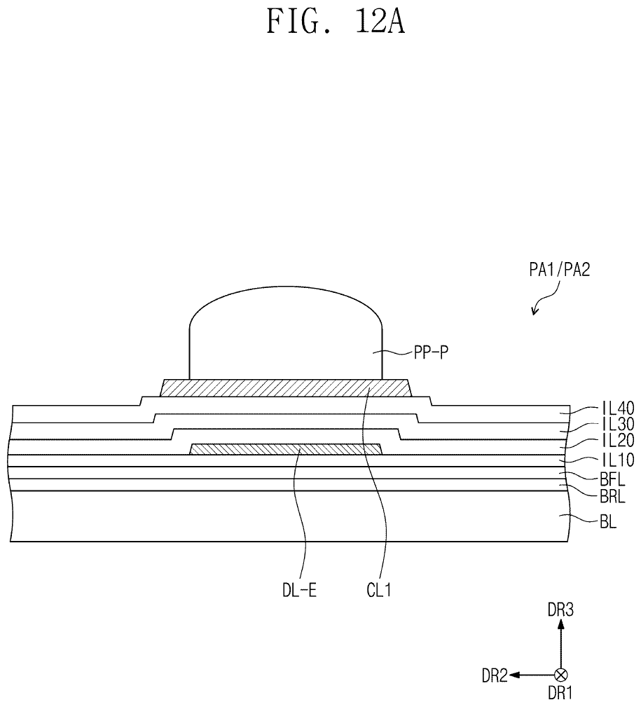

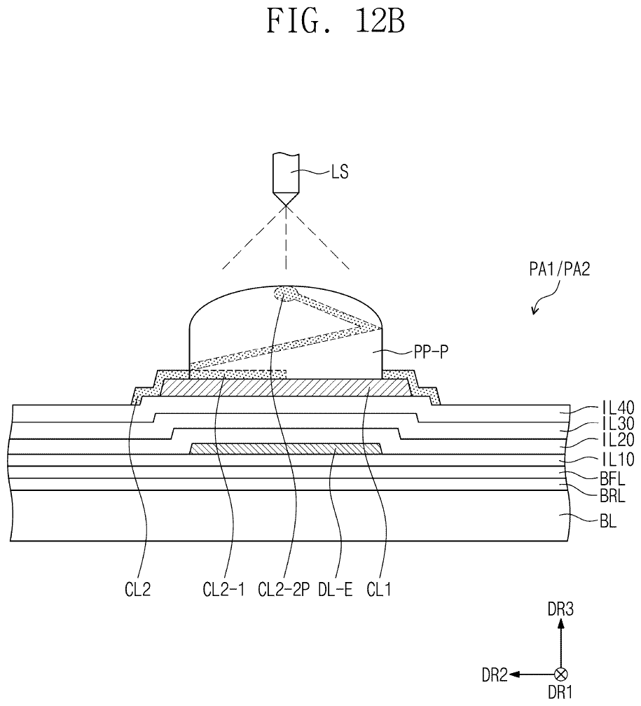

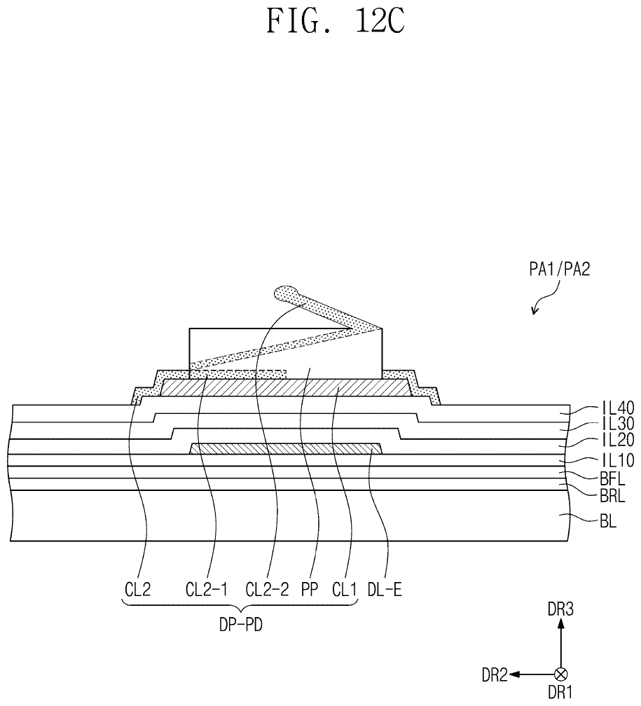

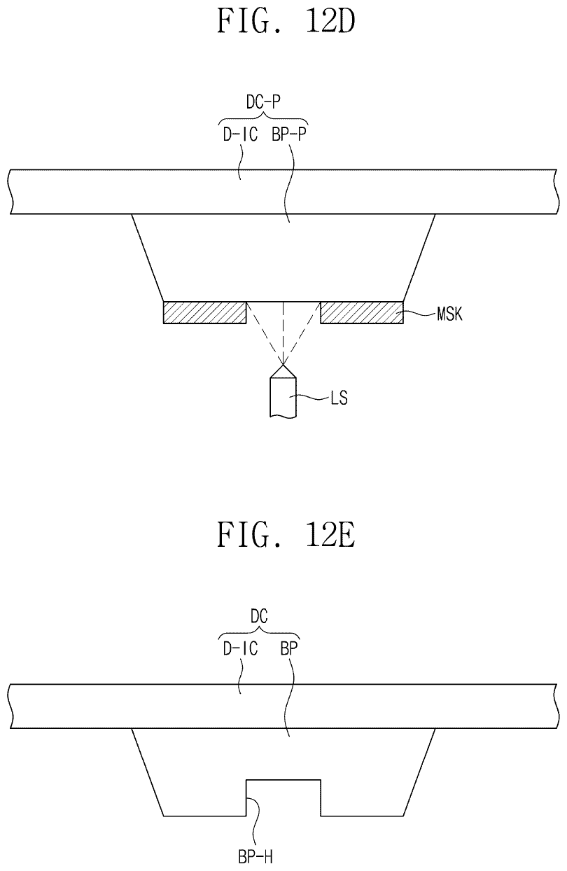

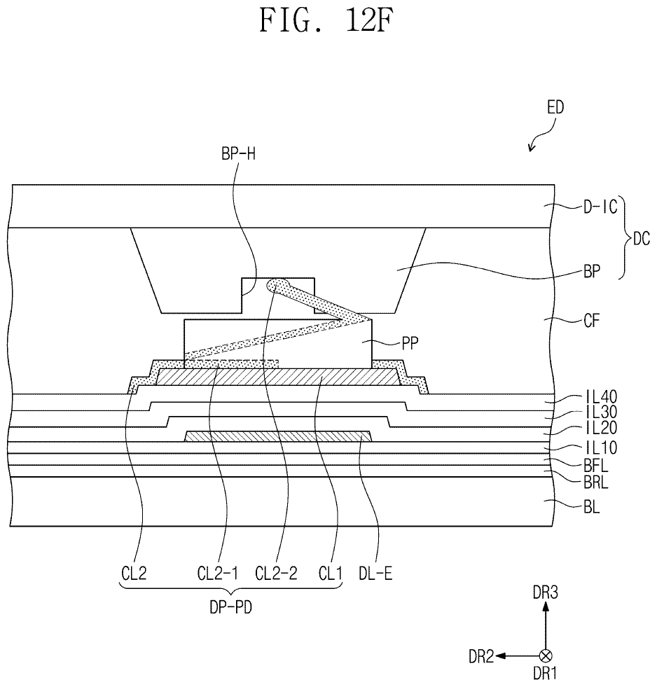

FIGS. 12A to 12F are schematic sectional views illustrating steps of a bonding method of the electronic device ED according to some example embodiments of the present disclosure. FIGS. 12A to 12F are illustrated based on the cross-section of the form in which the insulating pattern PP is disposed. Description of components identical to the components described with reference to FIG. 10B will be omitted.

Referring to FIG. 12A, a preliminary insulating pattern PP-P is coated on the first conductive pattern CL1. The preliminary insulating pattern PP-P may include a photosensitive polyimide resin. The preliminary insulating pattern PP-P is exposed to ultraviolet (UV) light and cured for one hour. The preliminary insulating pattern PP-P may have a semicircular shape convex in the third direction DR3.

Referring to FIG. 12B, the first metal line portion CL2-1 having a spiral shape and a second preliminary metal line portion CL2-2P surrounding the center of the preliminary insulating pattern PP-P are formed on the outer surface of the preliminary insulating pattern PP-P. The first metal line portion CL2-1 and the second preliminary metal line portion CL2-2P may be formed through a deposition process and a patterning process. Thereafter, the second conductive pattern CL2 making contact with the first conductive pattern Cl2 may be formed through an additional deposition process.

FIGS. 12B and 12C schematically illustrate a process of etching an upper portion of the preliminary insulating pattern PP-P by applying a laser LS to the upper portion of the preliminary insulating pattern PP-P. When the laser LS is applied to the upper portion of the preliminary insulating pattern PP-P, the upper portion of the preliminary insulating pattern PP-P is partially removed, and the insulating pattern PP having a rectangular shape is formed. That is, a portion of the preliminary insulating pattern PP-P may be removed by laser ablation, but the first metal line portion CL2-1 and the second metal line portion CL2-2 may be subjected to patterning without being removed. As the preliminary insulating pattern PP-P is removed, the second metal line portion CL2-2 may have a shape protruding from the insulating pattern PP.

Referring to FIG. 12D, a preliminary driver chip DC-P including a driver integrated circuit D-IC and a preliminary bump BP-P is illustrated. As illustrated in FIG. 12D, a mask MSK is disposed on the preliminary bump BP-P, and the preliminary bump BP-P is subjected to patterning by applying a laser LS. In FIG. 12E, the bump BP including the hole BP-H is formed.

As illustrated in FIG. 12F, the second metal line portion CL2-2 may be inserted into the hole BP-H of the bump BP and may be brought into contact with the bump BP. That is, the signal pad DP-PD and the driver chip DC of the electronic device ED may be bonded, and thus electronic components may be electrically connected with each other.

According to the present disclosure, the display panel and the electronic component may be bonded to each other without an anisotropic conductive film. The pad of the display panel may include the insulating pattern disposed on the conductive pattern and the metal line portion protruding from the insulating pattern, and the protruding metal line portion may be electrically connected with the electric component by making contact with the hole of the electronic component. Accordingly, the display panel and the electronic component may be bonded to each other at relatively lower temperature and pressure. Thus, cracks in the display panel may be reduced so that the durability of the display panel may be improved.

According to the present disclosure, the signal pad of the display panel may include the insulating pattern disposed on the conductive pattern and the metal line portion protruding from the insulating pattern. Accordingly, accessibility between the bump of the electronic component and the pad may be improved, and thus bonding characteristics may be improved. In addition, the display panel and the electronic component may be bonded to each other at relatively lower temperature and pressure, and thus damage to the display panel due to heat may be alleviated.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. An electronic device comprising:
a display panel including a display area and a non-display area adjacent to the display area; and
an electronic component in the non-display area and electrically connected to the display panel,
the display panel comprising:
a pixel;
a signal line electrically connected to the pixel; and
a signal pad electrically connected with the signal line,
the signal pad including:
a first conductive pattern electrically connected to an end portion of the signal line;
an insulating pattern on the first conductive pattern; and
a second conductive pattern configured to contact the first conductive pattern, the second conductive pattern comprising a first metal line portion configured to contact an outer surface of the insulating pattern and a second metal line portion configured to extend from the first metal line portion and protrude from the insulating pattern, and
the electronic component including a bump defining a hole configured to contact the second metal line portion.

2. The electronic device of claim 1, wherein the first metal line portion has a spiral shape.

3. The electronic device of claim 1, wherein
the second metal line portion comprises a first portion having a same thickness as the first metal line portion and a second portion having a greater thickness than the first portion, the second portion being configured to extend from the first portion, and
the second portion is inserted into the hole of the bump.

4. The electronic device of claim 1, further comprising:
an adhesive layer configured to couple the display panel and the electronic component,
wherein the insulating pattern and the bump are spaced apart from each other, and
wherein the adhesive layer fills a separation space between the insulating pattern and the bump.

5. The electronic device of claim 4, wherein the adhesive layer includes an acrylic resin.

6. The electronic device of claim 1, wherein
the display panel further comprises at least one insulating layer between the end portion of the signal line and the first conductive pattern, and
the first conductive pattern is electrically connected to the end portion of the signal line through a contact hole defined by the at least one insulating layer.

7. The electronic device of claim 1, wherein
the signal pad extends in one direction on a plane,
the insulating pattern comprises a plurality of insulating patterns, and
the plurality of insulating patterns are spaced apart from one another in the one direction.

8. The electronic device of claim 7, wherein a gap between two insulating patterns adjacent to each other among the plurality of insulating patterns ranges from 8 μm to 12 μm.

9. The electronic device of claim 7, wherein
the display panel further comprises at least one insulating layer between the end portion of the signal line and the first conductive pattern,
the end portion of the signal line and the first conductive pattern are connected through a plurality of contact holes defined by the at least one insulating layer, and
the plurality of contact holes and the plurality of insulating patterns alternate with one another in the one direction.

10. The electronic device of claim 7, wherein
the hole comprises a plurality of holes on a plane and the second metal line portion comprises a plurality of second metal line portions on the plane,
the plurality of holes are spaced apart from one another in the one direction and the plurality of the second metal line portions are spaced apart from one another in the one direction, and
the plurality of holes correspond to the plurality of the second metal line portions configured to protrude from the plurality of insulating patterns, respectively.

11. The electronic device of claim 10, wherein a length of the bump in the one direction is longer than a length of the insulating pattern in the one direction.

12. The electronic device of claim 1, wherein the hole of the bump has a depth of 2 μm to 4 μm.

13. The electronic device of claim 1, wherein each of the first metal line portion and the second metal line portion comprises a first layer, a second layer on the first layer, and a third layer on the second layer, the third layer including a same material as the first layer.

14. The electronic device of claim 1, wherein the insulating pattern has a thickness greater than or equal to 2 μm and less than 4 μm.

15. A display panel comprising:
a pixel;
a signal line electrically connected to the pixel; and
a signal pad electrically connected with the signal line,
the signal pad comprising:
a first conductive pattern electrically connected to an end portion of the signal line;
an insulating pattern on the first conductive pattern; and
a second conductive pattern configured to contact the first conductive pattern, the second conductive pattern comprising a first metal line portion configured to contact an outer surface of the insulating pattern and a second metal line portion configured to extend from the first metal line portion and protrude from the insulating pattern.

16. The display panel of claim 15, wherein the first metal line portion has a spiral shape.

17. The display panel of claim 15, wherein the second metal line portion comprises a first portion having a same thickness as the first metal line portion and a second portion having a greater thickness than the first portion, the second portion being configured to extend from the first portion.

18. The display panel of claim 15, wherein each of the first metal line portion and the second metal line portion comprises a first layer, a second layer on the first layer, and a third layer on the second layer, the third layer including a same material as the first layer.

19. The display panel of claim 15, wherein
the signal pad extends in one direction on a plane,
the insulating pattern comprises a plurality of insulating patterns, and
the plurality of insulating patterns are spaced apart from one another in the one direction.

20. The display panel of claim 19, wherein a gap between two insulating patterns adjacent to each other among the plurality of insulating patterns ranges from 8 μm to 12 μm.
